(19) United States
(12) Patent Application Publication
(10) Pub. No.: US 2024/0162054 A1
(43) Pub. Date: May 16, 2024

(54) SUBSTRATE PROCESSING METHOD AND SUBSTRATE PROCESSING SYSTEM

(71) Applicant: SCREEN Holdings Co., Ltd., Kyoto (JP)

(72) Inventor: Noritake SUMI, Kyoto (JP)

(21) Appl. No.: 18/508,972

(22) Filed: Nov. 14, 2023

(30) Foreign Application Priority Data
Nov. 16, 2022 (JP) 2022-183329

(51) Int. Cl. H01L 21/67; B08B 3/04; B08B 5/02; B08B 7/00

(52) U.S. Cl. CPC H01L 21/67034; B08B 3/04; B08B 5/02; B08B 7/0014; B08B 7/0021; H01L 21/68707

(57) ABSTRACT

A substrate processing method in accordance with the present invention includes forming a liquid film on an upper surface of a substrate by a wet processing apparatus; carrying the substrate having the liquid film formed thereon into a chamber of a supercritical processing apparatus by a conveyor device; and processing a substrate by a processing fluid in a supercritical state in the chamber by the supercritical processing apparatus. The method further includes blowing a gas toward a lower surface of the substrate supported in a horizontal posture by a gas discharger for at least a part of a period after the formation of the liquid film on the substrate during which the substrate is outside the chamber.

### CROSS REFERENCE TO RELATED APPLICATION

The disclosure of Japanese Patent Application No. 2022-183329 filed on Nov. 16, 2022 including specification, drawings and claims is incorporated herein by reference in its entirety.

### BACKGROUND OF THE INVENTION

### 1. Field of the Invention

This invention relates to a substrate processing technique for processing a substrate by a processing fluid in a supercritical state in a processing space of a processing container.

### 2. Description of the Related Art

A processing process of various substrates such as semiconductor substrates and glass substrates for display device includes a processing of substrates by various processing fluids. Such a processing may be performed in an airtight processing container for the purpose of efficiently using the processing fluid and preventing scattering to outside. For example, in a processing apparatus described in JP 2021-136373A, a substrate to be processed is carried into an internal space of a chamber having an opening in a side surface while being placed on a flat plate-like support tray integrated with a lid, and the internal space is sealed by closing the opening by the lid. From this state, a processing fluid in a supercritical state is introduced and the substrate is processed. Since the internal space of the chamber is formed to be slightly larger than the enveloping shape of the substrate and the support tray, it is possible to reduce the use amount of the processing fluid and improve processing efficiency.

In the technique of this type, the substrate may be carried into the chamber with a liquid spread on a surface of the substrate to avoid the contact of the exposed substrate before the processing with air or prevent the collapse of a fine pattern formed on the substrate surface. Also in the above conventional technique, the surface of the substrate being carried in is covered with a liquid film of an organic solvent such as IPA (isopropyl alcohol).

### SUMMARY OF INVENTION

The liquid forming such a liquid film contributes to the surface protection of the substrate during conveyance, but should be removed in an early stage in a supercritical processing thereafter. However, if the substrate is carried in while being placed on the support tray as in the above conventional technique, it is particularly difficult to discharge the liquid having entered a minute gap between the lower surface of the substrate and the support tray. Thus, problems possibly occur such as a long time required for a processing of completely discharging the liquid and a defective processing result due to the liquid remaining a long time.

From this, the lower surface of the substrate to be carried into the chamber is preferably in a state with least adhesion of the liquid. However, it is difficult to completely eliminate a movement of the liquid around to the lower surface side during a period from the formation of the liquid to the carry-in into the chamber. Therefore, it is required to remove the liquid adhering to the lower surface of the substrate as much as possible until the substrate is carried into the chamber. The conventional technique, in which such a measure was not taken, had a room for improvement on this point.

This invention was developed in view of the above problem and aims to reduce the amount of a liquid adhering to the lower surface of a substrate before the substrate is carried into a chamber in a substrate processing technique for processing the substrate using a processing fluid in a supercritical state in the chamber.

One aspect of this invention is directed to a substrate processing method. The method comprises: forming a liquid film on an upper surface of a substrate by a wet processing apparatus; carrying the substrate having the liquid film formed thereon into a chamber of a supercritical processing apparatus by a conveyor device; processing a substrate by a processing fluid in a supercritical state in the chamber by the supercritical processing apparatus; and blowing a gas toward a lower surface of the substrate supported in a horizontal posture by a gas discharger for at least a part of a period after the formation of the liquid film on the substrate during which the substrate is outside the chamber.

In the invention thus configured, the gas is blown to the lower surface of the substrate while the substrate is outside the chamber after the formation of the liquid film. In this way, a liquid adhering to the lower surface of the substrate is blown off and removed from the lower surface of the substrate. As a result, the amount of the liquid brought into the chamber when the substrate is accommodated into the chamber can be reduced and, particularly, the amount of the liquid brought into while adhering to the lower surface of the substrate can be largely reduced.

As described above, in the invention, the liquid adhering to the substrate lower surface can be swept away by first introducing the pressurized gas to a lower surface side of the support tray accommodated into the chamber together with the substrate. Thus, a time required to remove the remaining liquid can be shortened in a supercritical processing thereafter, and processing failures due to the remaining liquid can be suppressed.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF THE DRAWINGS

FIG. 1 is a drawing showing a schematic configuration of a substrate processing system to which the invention can be applied.

FIG. 2 is a flow chart summarizing a process performed by this substrate processing system.

FIG. 3 is a diagram showing a configuration example of the wet processing apparatus.

FIGS. 4A to 4D are diagrams schematically showing an operation flow of the wet processing apparatus.

FIG. 5 is a side view showing the configuration of the supercritical processing apparatus.

FIGS. 6A to 6D are diagrams schematically showing a state of substrate transfer.

FIGS. 7A and 7B are diagrams showing a first embodiment for the blowing of a gas.

FIGS. 8A and 8B are diagrams showing a second embodiment for the blowing of a gas.

FIGS. 9A and 9B are diagrams showing a third embodiment for the blowing of a gas.

### DETAILED DESCRIPTION OF THE PREFERRED EMBODIMENTS

### System Configuration

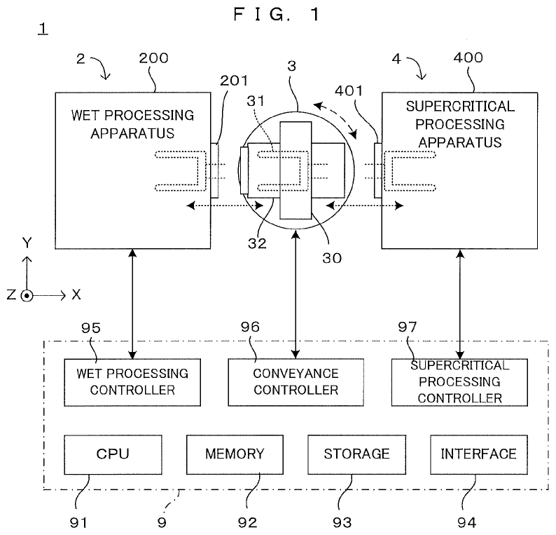

FIG. 1 is a drawing showing a schematic configuration of a substrate processing system to which the invention can be applied. XYZ orthogonal coordinate axes are set as shown in FIG. 1 to show directions in each figure in a unified manner below. Here, an XY plane represents a horizontal plane. Further, a Z axis represents a vertical axis, more particularly, a (−Z) direction represents a vertically downward direction.

This substrate processing system 1 is a processing system for wet-processing various substrates such as semiconductor wafers by supplying a processing fluid to the upper surfaces of the substrates and, thereafter, drying the substrates, and has a suitable system configuration to carry out a substrate processing method according to the invention. That is, the substrate processing system 1 is provided with a wet processing apparatus 2, a conveyor device 3, a supercritical processing apparatus 4 and a controller 9.

The wet-processing apparatus 2, the conveyor device 3 and the supercritical processing apparatus 4 are arranged in this order along a (+X) direction. Main components of the wet processing apparatus 2 are accommodated inside a processing chamber 200, an opening (not shown), through which the substrate is carried in and out, is provided in a side surface on a (+X) side of the processing chamber 200, and an openable and closable shutter 201 is provided for this opening. On the other hand, main components of the supercritical processing apparatus 4 are accommodated inside a processing chamber 400, an opening (not shown), through which the substrate is carried in and out, is provided in a side surface on a (−X) side of the processing chamber 400, and an openable and closable shutter 401 is provided for this opening.

The wet processing apparatus 2 receives a substrate to be processed and performs a predetermined wet processing. Contents of the processing is not particularly limited. The conveyor device 3 carries out the substrate after the wet processing from the wet processing apparatus 2, conveys and carries the substrate into the supercritical processing apparatus 4. The supercritical processing apparatus 4 performs a drying processing (supercritical drying processing) using a processing fluid in a supercritical state for the substrate carried thereinto. These are installed in a clean room. Therefore, the conveyor device 3 conveys the substrate S in an atmosphere and under an atmospheric pressure.

The control unit 90 realizes a predetermined process by controlling these components of the apparatus. For this purpose, the control unit 90 includes a CPU 91 for executing various control programs, a memory 92 for temporarily storing processing data, a storage 93 for storing the control programs to be executed by the CPU 91, an interface 94 for information exchange with a user and an external apparatus, and the like. Operations of the apparatus to be described later are realized by the CPU 91 causing each component of the apparatus to perform a predetermined operation by executing the control program written in the storage 93 in advance.

The CPU 91 executes a predetermined control program, whereby functional blocks such as a wet processing controller 95 for controlling the operation of the wet processing apparatus 2, a conveyance controller 96 for controlling the operation of the conveyor device 3 and a supercritical processing controller 97 for controlling the operation of the supercritical processing apparatus 4 are realized by software in the controller 9. Note that each of these functional blocks may be at least partially configured by dedicated hardware.

Here, various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates can be applied as the “substrate” in this embodiment. Although the substrate processing apparatus used in processing semiconductor wafers is mainly described as an example with reference to the drawings below, application to the processing of various substrates illustrated above is also possible.

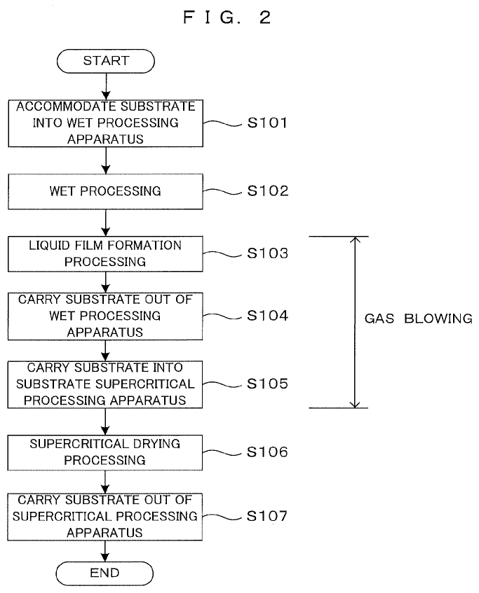

FIG. 2 is a flow chart summarizing a process performed by this substrate processing system. This substrate processing system 1 receives a substrate S to be processed and sequentially performs the wet processing using a processing liquid and the supercritical drying processing using a supercritical processing fluid. Specifically, the process is performed as follows. The substrate S to be processed is accommodated into the wet processing apparatus 2 constituting the substrate processing system 1 (Step S101). The substrate S may be directly carried in by an external conveyor device or may be carried in via the conveyor device 3 from an external conveyor.

The wet processing apparatus 2 applies the wet processing to the substrate S using the predetermined processing liquid (Step S102). Thereafter, a liquid film formation processing of forming a liquid film on a surface by an organic solvent such as IPA is performed (Step S103). For example, if a fine pattern is formed on the surface of the substrate S, the pattern may collapse due to a surface tension of the liquid remaining on and adhering to the substrate S. Further, watermarks may remain on the surface of the substrate S due to incomplete drying. Further, the surface of the substrate S may undergo deterioration such as oxidation due to contact with outside air. To avoid such problems, the substrate S may be conveyed with the surface (pattern forming surface) thereof covered with a liquid.

For example, if a cleaning liquid mainly contains water, the substrate is conveyed in a state where a liquid film is formed by a liquid having a lower surface tension than water and having low corrosiveness to the substrate, e.g. an organic solvent such as IPA or acetone. That is, the substrate S is carried out from the wet processing apparatus 2 by the conveyor device 3 while being horizontally supported and having a liquid film formed on the upper surface thereof (Step S104), further conveyed and finally carried into the supercritical processing apparatus 4 (Step S105).

The supercritical processing apparatus 4 applies the supercritical drying processing to the substrate S conveyed thereto (Step S106). The processing fluid in the supercritical state has a very low surface tension and a low fluidity. Thus, the processing fluid enters the fine pattern formed on the surface of the substrate S and replaces the liquid in the pattern. For example, in the case of using carbon dioxide as the supercritical processing fluid, the liquid forming the liquid film can be efficiently replaced and removed from the substrate surface since carbon dioxide dissolves into the organic solvent well.

The supercritical processing fluid is vaporized without via a liquid phase, and discharged. The liquid adhering to the substrate S is replaced by the supercritical processing fluid and discharged, and the processing fluid is also discharged, whereby the substrate S in a dry state is obtained. Since a gas-liquid interface is not formed in this process, the pattern collapse due to a surface tension can be avoided. The substrate S after the processing is carried out from the supercritical processing apparatus 4 by the conveyor device 3 and transferred to the following process. Contents of the following process are arbitrary.

The structure of each constituent element of the substrate processing system 1 for performing the series of processings described above are described more specifically.

A conveyor robot 30 provided with a hand 31 on the tip of an unillustrated telescopic and rotatable arm is provided in the conveyor device 3. As shown by broken line arrows, the conveyor robot 30 is rotatable about a Z axis. The hand 31 can support the substrate by partially contacting the lower surface of the substrate. As shown by dotted lines in FIG. 1, the hand 31 is stored inside a cover 32 and movable back and forth to both the wet processing apparatus 2 and the supercritical processing apparatus 4 by advancing to outside from the cover 32 if necessary. In this way, the substrate can be carried into and out from each of the wet processing apparatus 2 and the supercritical processing apparatus 4. The operation of the conveyor robot 30 is controlled by the conveyance controller 96 of the controller 9.

A conveyor robot described in JP 2020-188228A previously disclosed by the applicant of this application is suitably applicable as the conveyor robot of this type. Since this publication can be referred to, the specific structure of the conveyor robot 31 is not described here.

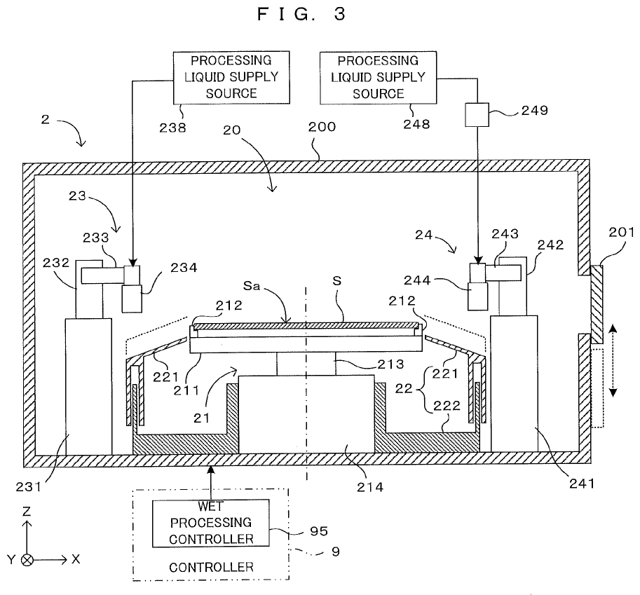

FIG. 3 is a diagram showing a configuration example of the wet processing apparatus. More specifically, FIG. 3 is a side view showing the overall configuration of the wet processing apparatus 2. This wet processing apparatus 2 is an apparatus for processing a substrate by supplying the processing liquid to the upper surface of the substrate. The operation of the wet processing apparatus 2 is controlled by the wet processing controller 95 of the controller 9.

The wet processing apparatus 2 performs a surface processing of the substrate S and a wet processing such as washing by supplying the processing liquid to the upper surface of the substrate S. For this purpose, the wet processing apparatus 2 is provided with a substrate holder 21, a splash guard 22 and processing liquid suppliers 23, 24 inside the processing chamber 200. The operations of these are controlled by the wet processing controller 95 provided in the controller 9.

The substrate holder 21 includes a disk-like spin chuck 211 having a diameter nearly equal to that of the substrate S, and a plurality of chuck pins 212 are provided on a peripheral edge part of the substrate S. The chuck pins 212 are in contact with the peripheral edge part of the substrate S to support the substrate S, whereby the spin chuck 211 can hold the substrate S in a horizontal posture with the substrate S separated from the upper surface of the spin chuck 211.

The spin chuck 211 is so supported that the upper surface thereof is horizontal by a rotary support shaft 213 extending downward from a central part of the lower surface of the spin chuck 211. The rotary support shaft 213 is rotatably supported by a rotating mechanism 214 mounted in a bottom part of the processing chamber 200. The rotating mechanism 214 includes an unillustrated built-in rotary motor. The rotary motor rotates in response to a control command from the controller 9, whereby the spin chuck 211 directly coupled to the rotary support shaft 213 rotates about a vertical axis indicated by a dashed-dotted line. In FIG. 3 an up-down direction is a vertical direction. In this way, the substrate S is rotated about the vertical axis while being held in the horizontal posture.

The splash guard 22 is provided to laterally surround the substrate holder 21. The splash guard 22 includes a substantially tubular cup 221 provided to cover the peripheral edge part of the spin chuck 211 and a liquid receiver 222 provided below an outer peripheral part of the cup 221. The cup 211 is raised and lowered in response to a control command from the controller 9. The cup 221 is raised and lowered between a lower position where an upper end part of the cup 221 is lowered to below the peripheral edge part of the substrate S held by the spin chuck 211 as shown by solid lines in FIG. 3 and an upper position where the upper end part of the cup 221 is located above the peripheral edge part of the substrate S as shown by dotted lines in FIG. 3.

As shown by solid lines in FIG. 3, when the cup 221 is at the lower position, the substrate S held by the spin chuck 211 is exposed to the outside of the cup 221. Thus, the cup 211 is, for example, prevented from becoming an obstacle when the substrate S is carried to and from the spin chuck 211.

Further, as indicated by dotted lines in FIG. 3, the cup 221 surrounds the peripheral edge part of the substrate S held by the spin chuck 211 when being at the upper position. In this way, the processing liquid shaken off from the peripheral edge part of the substrate S during liquid supply to be described later is prevented from scattering in the chamber 200, and the processing liquid can be reliably collected. That is, by the rotation of the substrate S, droplets of the processing liquid shaken off from the peripheral edge part of the substrate S adhere to the inner wall of the cup 221, flow down and are gathered and collected by the liquid receiver 222 arranged below the cup 221. To individually collect a plurality of processing liquids, cups may be concentrically provided at a plurality of levels.

The processing liquid supplier 23 is structured such that a nozzle 234 is attached to the tip of an arm 233 horizontally extending from a rotary support shaft 232 provided rotatably with respect to a base 231 fixed in the processing chamber 200. The rotary support shaft 232 rotates in response to a control command from the controller 9, whereby the arm pivots and the nozzle 234 on the tip of the arm 233 moves between a retracted position retracted laterally from above the substrate S and a processing position above the substrate S.

The nozzle 234 is connected to a processing liquid supply source 238. If an appropriate processing liquid is sent out from the processing liquid supply source 238, the processing liquid is discharged toward the substrate S from the nozzle 234. By supplying the processing liquid from the nozzle 234 positioned above a center of rotation of the substrate S while rotating the substrate S by the rotation of the spin chuck 211 at a relatively low speed, an upper surface Sa of the substrate S is processed by the processing liquid. Liquids having various functions such as developers, etching liquids, cleaning liquids and rinsing liquids can be used as the processing liquid, and a composition of the processing liquid is arbitrary. Further, the processing may be performed with a plurality of types of processing liquids combined.

Another processing liquid supplier 24 also has a configuration corresponding to the first processing liquid supplier 23 described above. That is, processing liquid supplier 24 includes a base 241, a rotary support shaft 242, an arm 243, a nozzle 244 and the like, and the configurations of these are the same as those of the corresponding components of the first processing liquid supplier 23. The rotary support shaft 242 rotates in response to a control command from the controller 9, whereby the arm 243 pivots. The nozzle 244 on the tip of the arm 243 supplies a processing liquid to the upper surface Sa of the substrate S.

In this wet processing apparatus 2, the second processing liquid supplier 24 is used for the purpose of forming a liquid film for dry prevention on the substrate S after the wet processing. That is, the substrate S after the wet processing is conveyed to the supercritical processing apparatus 4 and receives a supercritical drying processing. To prevent the surface of the substrate S from being exposed and oxidized during conveyance and prevent the collapse of the fine pattern formed on the surface, the substrate S is conveyed with the surface thereof covered with a puddle-like liquid film.

A substance having a lower surface tension than water, which is a main component of a processing liquid used in a cleaning processing, e.g. an organic solvent such as isopropyl alcohol (IPA) or acetone, is used as the liquid for constituting the liquid film.

Although two processing liquid suppliers are provided in the wet processing apparatus 2 here, the number, structures and functions of the processing liquid suppliers are not limited to these. For example, only one processing liquid supplier may be provided or three or more processing liquid suppliers may be provided. Further, one processing liquid supplier may include a plurality of nozzles. For example, a plurality of nozzles may be provided on the tip of one arm. Further, the processing liquid is not only discharged with the nozzle positioned at the predetermined position as described above, but also may be, for example, discharged while the nozzle is scanned and moved along the upper surface Sa of the substrate S. Further, a gas supplier including a nozzle for discharging a gas may be further provided. Further, at least one of a plurality of nozzles provided in the processing liquid supplier may discharge a gas.

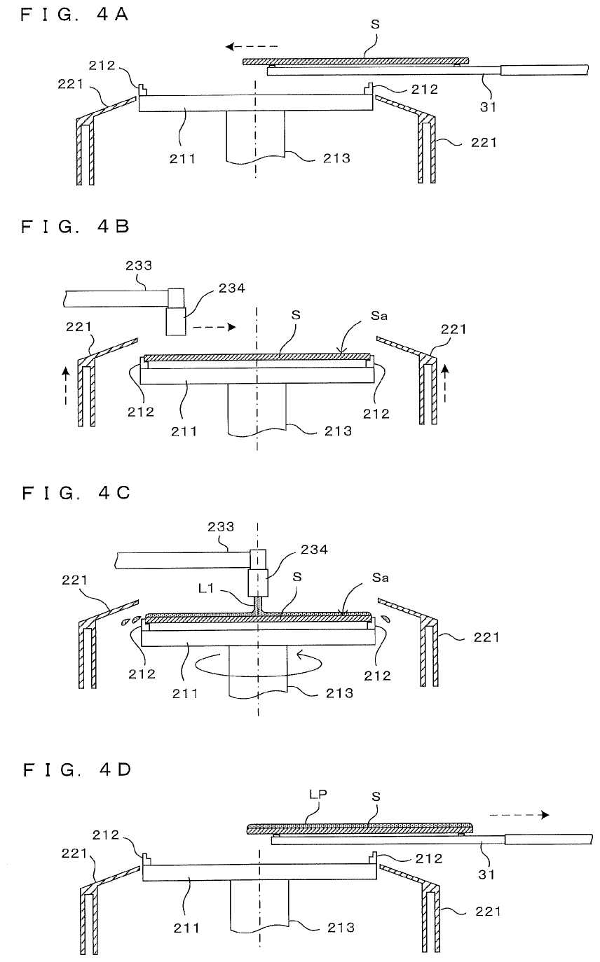

FIGS. 4A to 4D are diagrams schematically showing an operation flow of the wet processing apparatus. In FIGS. 4A, 4B and 4D, a broken line arrow indicates a moving direction of each part. As shown in FIG. 4A, with the cup 221 located at the lower position, the shutter 201 (FIG. 3) of the processing chamber 200 is opened and the unprocessed substrate S supported by the hand 31 of the conveyor device 3 is carried in. After the substrate S is transferred to the chuck pins 212 provided on the peripheral edge part of the upper surface of the spin chuck 211, the hand 31 is retracted and the shutter 201 is closed.

In an example of the wet processing using the nozzle 234, the cup 221 is raised and positioned at the upper position and the nozzle 234 is moved toward the center of rotation of the substrate S indicated by a dashed-dotted line as shown in FIG. 4B. Then, as shown in FIG. 4C, with the nozzle 234 positioned at the center of rotation of the substrate S, the substrate S is rotated at a predetermined rotation speed and a processing liquid L1 is discharged from the nozzle 234. The processing liquid L1 flows outward along the upper surface of the substrate S due to a centrifugal force and is finally shaken off from the peripheral edge part of the substrate S. The shaken-off liquid is collected by the cup 221.

Further, a liquid film formation processing (Step S103) is performed before the substrate S is carried out. That is, the nozzle 244 for liquid film formation is positioned at the center of rotation of the substrate S and the processing liquid for liquid film formation, e.g. IPA, is discharged from the nozzle 244. In this way, the upper surface Sa of the substrate S is covered with a liquid film LP. A thickness of the liquid film can be adjusted by the rotation speed of the substrate S.

After the supply of the processing liquid and the rotation of the substrate S are stopped, the substrate S having the liquid film LP formed thereon is carried out. That is, the cup 221 is lowered to the lower position and the hand 31 of the conveyor robot 30 carries out the substrate S kept in the horizontal posture. The substrate S is conveyed to the supercritical processing apparatus 4 together with the liquid film LP.

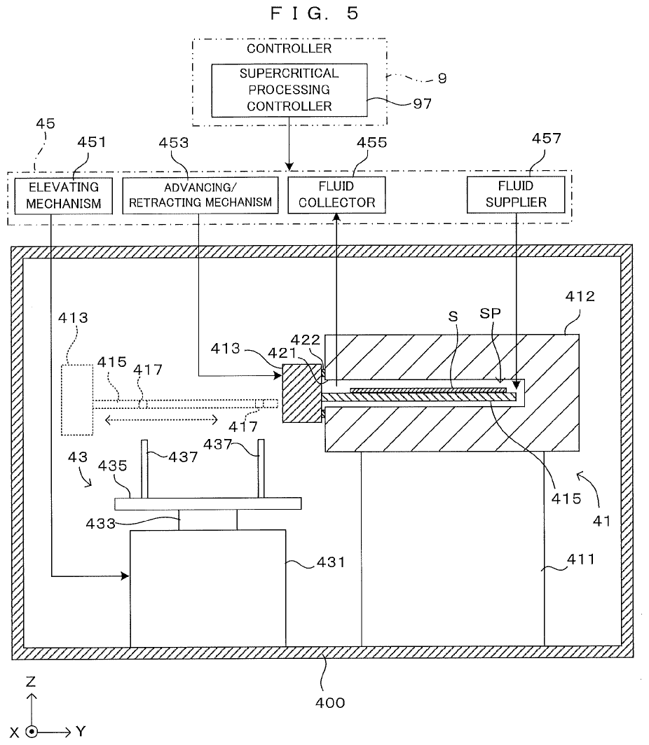

FIG. 5 is a side view showing the configuration of the supercritical processing apparatus. The supercritical processing apparatus 4 is an apparatus for applying the drying processing using the processing fluid in a supercritical state to the substrate S after the wet processing. More specifically, the supercritical processing apparatus 4 is an apparatus for finally bringing the substrate S to a dry state by discharging the processing fluid after receiving the substrate S after the wet processing and replacing the liquid remaining on the substrate S by the processing fluid in the supercritical state.

The supercritical processing apparatus 4 is provided with a processing unit 41 and a transfer unit 43 provided in the processing chamber 400 and a supply unit 45. The processing unit 41 serves as an executor of the supercritical drying processing. The transfer unit 43 receives the substrate S after the wet processing conveyed by the conveyor device 3, carries the substrate S into the processing unit 41 and transfers the processed substrate S from the processing unit 41 to an external conveyor device. The supply unit 45 supplies chemical substances, power, energy and the like necessary for the processing to the processing unit 41 and the transfer unit 43. These operations are controlled by the controller 9, particularly by the supercritical processing controller 97.

The processing unit 41 is structured such that a processing chamber 412 is mounted on a pedestal 411. The processing chamber 412 is configured by a combination of several metal blocks and the inside thereof is hollow and constitutes a processing space SP. The substrate S to be processed is carried into the processing space SP and processed. A slit-like opening 421 elongated in the X direction is formed in a side surface on the (−Y) side of the processing chamber 412. The processing space SP and an outside space communicate via the opening 421. A cross-sectional shape of the processing space SP is substantially the same as an opening shape of the opening 421. That is, the processing space SP is a hollow having a cross-sectional shape long in the X direction and short in the Z direction and extending in the Y direction.

A lid member 413 is provided to close the opening 421 on the side surface on the (−Y) side of the processing chamber 412. The lid member 413 closes the opening 421 of the processing chamber 412, whereby an airtight processing container is configured. In this way, the substrate S can be processed under a high pressure in the internal processing space SP. A flat plate-like support tray 415 is mounted in a horizontal posture on a side surface on the (+Y) side of the lid member 413. The upper surface of the support tray 415 serves as a support surface on which the substrate S can be placed. The lid member 413 is supported horizontally movably in the Y direction by an unillustrated supporting mechanism.

The lid member 413 is made movable back and forth with respect to the processing chamber 412 by an advancing/retracting mechanism 453 provided in the supply unit 45. Specifically, the advancing/retracting mechanism 453 includes a linear motion mechanism such as a linear motor, a linear motion guide, a ball screw mechanism, a solenoid or an air cylinder. Such a linear motion mechanism moves the lid member 413 in the Y direction. The advancing/retracting mechanism 453 operates in response to a control command from the controller 9.

If the lid member 413 is separated from the processing chamber 412 by moving in the (−Y) direction and the support tray 415 is pulled out from the processing space SP to outside via the opening 421 as indicated by a dotted line, the support tray 415 becomes accessible. That is, the substrate S can be placed on the support tray 415 and the substrate S placed on the support tray 415 can be taken out. On the other hand, by a movement of the lid member 413 in the (+Y) direction, the support tray 415 is accommodated into the processing space SP. If the substrate S is placed on the support tray 415, the substrate S is carried into the processing space SP together with the support tray 415.

If the lid member 413 moves in the (+Y) direction and closes the opening 421, the processing space SP is sealed. A sealing member 422 is provided between the side surface on the (+Y) side of the lid member 413 and the side surface on the (−Y) side of the processing chamber 412, and the processing space SP is held airtight. The sealing member 422 is, for example, made of rubber. Further, the lid member 413 is fixed to the processing chamber 412 by an unillustrated lock mechanism. As just described, the lid member 413 is switched between a closing state (solid line) where the lid member 413 closes the opening 421 to seal the processing space SP and a separated state (dotted line) where the lid member 413 is largely separated from the opening 421 to enable the substrate S to be taken in and out.

With the airtight state of the processing space SP ensured, the substrate S is processed in the processing space SP. In this embodiment, a fluid supplier 457 provided in the supply unit 45 sends out a processing fluid of a substance usable in the supercritical processing, e.g. carbon dioxide, as the processing fluid and further brings the processing fluid into a supercritical state by pressurizing the processing fluid in the processing chamber 412. The processing fluid is supplied in a gas or liquid state to the processing unit 41. Carbon dioxide is a chemical substance suitable for the supercritical drying processing in having a property of entering the supercritical state at relatively low temperature and low pressure and dissolving into an organic solvent often used in substrate processing well. At a critical point at which carbon dioxide enters the supercritical state, an atmospheric pressure (critical pressure) is 7.38 MPa and a temperature (critical temperature) is 31.1° C.

If the processing fluid is filled into the processing space SP and the inside of the processing space SP reaches suitable temperature and pressure, the processing space SP is filled with the processing fluid in the supercritical state. In this way, the substrate S is processed by the supercritical fluid in the processing space 412. A fluid collector 455 is provided in the supply unit 45, and the fluid after the processing is collected by the fluid collector 455. The fluid supplier 457 and the fluid collector 455 are controlled by the supercritical processing controller 97.

The processing space SP has a shape and a volume capable of receiving the support tray 415 and the substrate S supported by the support tray 415. That is, the processing space SP has a substantially rectangular cross-sectional shape wider than a width of the support tray 415 in a horizontal direction and having a height larger than the sum of heights of the support tray 415 and the substrate S in the vertical direction, and has a depth capable of receiving the support tray 415. As just described, the processing space SP has a shape and a volume enough to receive the support tray 415 and the substrate S. Gaps between the support tray 415 and the substrate S and the inner wall surface of the processing space SP are tiny. Therefore, the amount of the processing fluid necessary to fill the processing space SP can be relatively small.

The fluid supplier 457 supplies the processing fluid to the processing space SP on a side further in the (+Y) direction than the end part on the (+Y) side of the substrate S. On the other hand, the fluid collector 55 discharges the processing fluid flowing in a space above the substrate S and a space below the support tray 415, out of the processing space SP, on a side further in the (−Y) direction than the end part on the (−Y) side of the substrate S. In this way, laminar flows of the processing fluid from the (+Y) side toward the (−Y) side are respectively formed above the substrate S and below the support tray 415 in the processing space SP.

The supercritical processing controller 97 of the controller 9 specifies the pressure and temperature in the processing space SP based on a detection result of an unillustrated detector and controls the fluid supplier 457 and the fluid collector 455 based on that result. In this way, the supply of the processing fluid into the processing space SP and the discharge of the processing fluid from the processing space SP are properly managed and the pressure and temperature in the processing space SP are adjusted according to a processing recipe determined in advance.

The transfer unit 43 is in charge of the transfer of the substrate S between the conveyor device 3 and the support tray 415. For this purpose, the transfer unit 43 is provided with a body 431, an elevating member 433, a base member 435 and a plurality of lift pins 437. The elevating member 433 is a columnar member extending in the Z direction, and supported movably in the Z direction with respect to the body 431 by an unillustrated supporting mechanism. The base member 435 having a substantially horizontal upper surface is mounted atop the elevating member 433. The plurality of lift pins 437 stand up from the upper surface of the base member 435. The respective lift pins 437 support the substrate S in a horizontal posture from below by the contact of upper end parts thereof with the lower surface of the substrate S. Three or more lift pins 437 having the upper end parts at the same height are desirably provided to stably support the substrate S in the horizontal posture.

The elevating member 433 is made movable up and down by an elevating mechanism 451 provided in the supply unit 45. Specifically, the elevating mechanism 451 includes a linear motion mechanism such as a linear motor, a linear motion guide, a ball screw mechanism, a solenoid or an air cylinder, and such a linear motion mechanism moves the elevating member 433 in the Z direction. The elevating mechanism 451 operates in response to a control command from the controller 9.

The base member 435 is moved up and down by upward and downward movements of the elevating member 433, and the plurality of lift pins 437 move up and down integrally with the base member 435. In this way, the transfer of the substrate S is realized between the transfer unit 43 and the support tray 415. More specifically, as shown by dotted lines in FIG. 5 the substrate S is transferred with the support tray 415 pulled out to the outside of the chamber. For this purpose, the support tray 415 is provided with through holes 417, through which the lift pins 437 are inserted. If the base member 435 is raised, the upper ends of the lift pins 437 reach above the upper surface of the support tray 415 through the through holes 417. In this state, the substrate S conveyed by the conveyor robot 30 is transferred from the hand 31 of the conveyor robot 30 to the lift pins 437. By lowering the lift pins 437, the substrate S is transferred from the lift pins 437 to the support tray 415. The substrate S can be carried out by a procedure opposite to the above one.

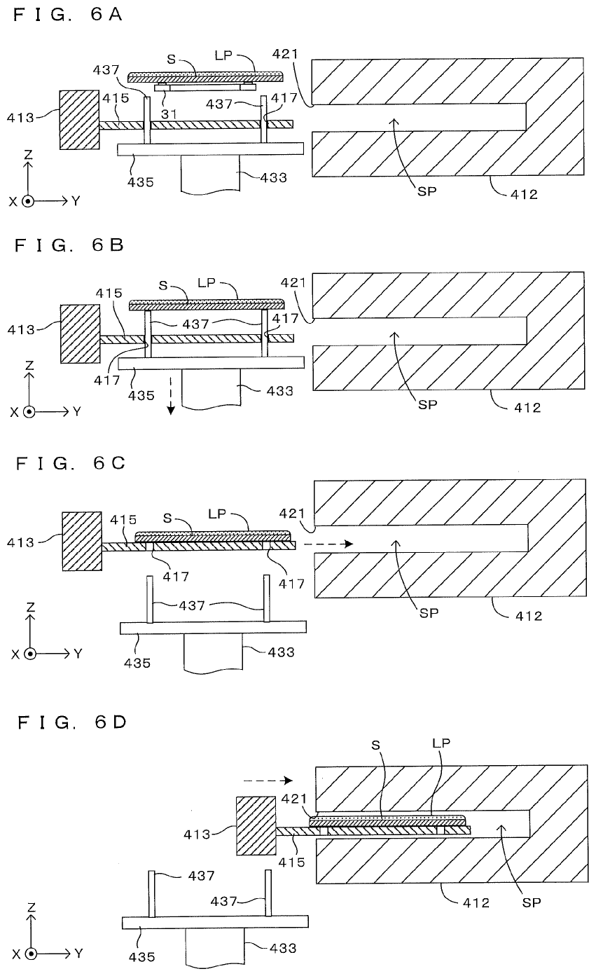

FIGS. 6A to 6D are diagrams schematically showing a state of substrate transfer. With reference to FIGS. 6A to 6D, the operation of each part in the transfer of the substrate S is described. An initial state of the apparatus is shown in FIG. 5. When the substrate S being carried in from outside is received from this state, the lid member 413 moves to the (−Y) side and the support tray 415 is pulled out from the processing chamber 412 as shown in FIG. 6A. The position of the support tray 415 at this time is referred to as a “pull-out position” below. By raising the elevating member 433, the lift pins 437 project from the upper surface (support surface) of the support tray 415. When the base member 435 is raised by raising the elevating member 433, the lift pins 437 project further upward than the support surface through the through holes 417.

As shown in FIG. 6A, the substrate S is conveyed while being held by the hand 31 provided in the conveyor robot 30 of the conveyor device 3. By causing the lift pins 437 to project further upward than the upper surface of the hand 31, the substrate S is transferred from the hand 31 to the lift pins 437. The shapes and arrangement of the hand 31 and the lift pins 437 are determined so that the hand 31 and the lift pins 437 do not interfere with each other. In this state, the hand 31 can be retracted laterally. As shown in FIG. 6B, by lowering the elevating member 433, the substrate S supported by the lift pins 437 is lowered.

Finally, as shown in FIG. 6C, the lower surface of the substrate S comes into contact with the upper surface of the support tray 415 and the lift pins 437 are lowered to below the support tray 415, whereby the substrate S is transferred from the lift pins 437 to the support tray 415. In this way, the substrate S is transferred from the conveyor robot 30 to the support tray 415. Thereafter, as shown in FIG. 6D, the lid member 413 moves in the (+Y) direction, whereby the substrate S is accommodated into the processing space SP of the processing chamber 412 together with the support tray 415.

The processed substrate S is carried out by a procedure opposite to the above. That is, as shown in FIG. 6C, after the processed substrate S is pulled out from the processing chamber 412 together with the support tray 415, the elevating member 433 is raised, whereby the lift pins 437 lift up the substrate S from the support tray 415. Then, as shown in FIG. 6A, the substrate S is transferred from the lift pins 437 to the hand 31 advancing from outside, whereby the substrate S is held by the hand 31. If the hand 31 carries out the substrate S to outside, the substrate S is put out from the supercritical processing apparatus 4.

As described above, the liquid film LP for surface protection is formed on the upper surface of the substrate S being carried into the supercritical processing apparatus 4. The liquid constituting the liquid film LP is replaced by the supercritical processing fluid introduced later, but the amount of the liquid to be brought into the processing chamber 412 is better to be small to enhance the efficiency of the processing. To reliably protect the entire upper surface of the substrate S, it is difficult to reduce the amount of the liquid constituting the liquid film LP.

On the other hand, the liquid desirably does not adhere to the lower surface of the substrate S. Since the substrate S is carried into the processing chamber 412 while being placed on the support tray 415, the liquid adhering to the lower surface of the substrate S enters a minute gap between the lower surface of the substrate S and the upper surface of the support tray 415. Then, a long time is required to replace and remove this liquid by the supercritical processing fluid, and the liquid remaining without being removed possibly becomes a cause of a processing failure. From this, the liquid adhering to the lower surface side is required to be sufficiently removed until the substrate S is carried into the processing chamber 412, more preferably before the substrate S is placed on the support tray 415.

Accordingly, in this substrate processing system, a gas is blown to the lower surface side of the substrate S for a certain period after the liquid film is formed on the upper surface Sa of the substrate S in the wet processing apparatus 2. In this way, the liquid adhering to the lower surface of the substrate S after the formation of the liquid film is removed. There are several ways of thinking for a specific configuration enabling this. Three embodiments are described below. Note that components common among the respective embodiments are denoted by common reference signs and repeated description is omitted.

### First Embodiment

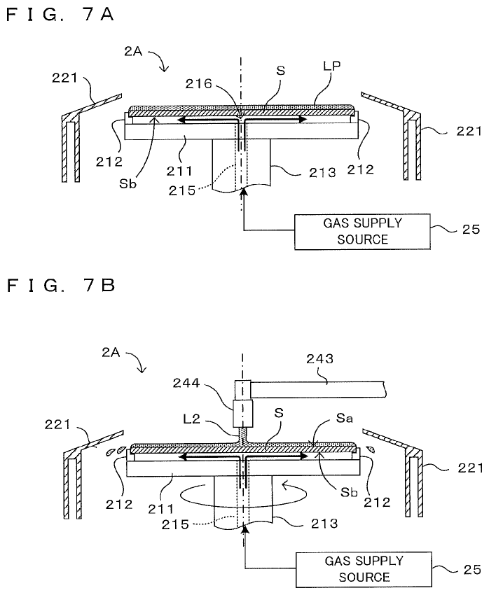

FIGS. 7A and 7B are diagrams showing a first embodiment for the blowing of a gas. More specifically, FIGS. 7A and 7B are diagrams showing an essential part of a wet processing apparatus 2A of the first embodiment. As shown in FIG. 7A, in this embodiment, a center of a rotary support shaft 213 is finished as a hollow, and the inside of the hollow serves as a gas flow passage 215. The upper end of the gas flow passage 215 is connected to a gas nozzle 216 provided on the upper surface of a spin chuck 211. An appropriate gas such as a nitrogen gas or dry air from a gas supply source 25 is supplied to the gas flow passage 215 in response to a control command from the controller 9. The supplied gas is blown toward the lower surface of a substrate S from the gas nozzle 216.

After a liquid film LP is formed on a substrate S and the rotation of the substrate S is stopped, the gas is supplied from the gas supply source 25 to the gas flow passage 215 provided inside the rotary support shaft 213. The gas is discharged from the gas nozzle 16 and blown to a lower surface Sb of the substrate S. In this way, a gas flow from a center toward a peripheral edge part is formed on the side of the lower surface Sb of the substrate S, and a liquid adhering to the lower surface Sb of the substrate S can be blown off by this gas flow.

Since the liquid may scatter around, a cup 221 is desirably positioned at an upper position. Note that, although the rotation of the substrate S is stopped here, the substrate S can also be rotated at a low speed as long as the liquid film LP on the upper surface Sa can be maintained.

Further, as shown in FIG. 7B, the gas may be blown to the lower surface Sb from when a processing liquid L2 for liquid film formation is supplied from a nozzle 244. In such a case, the liquid flowing around to the lower surface Sb of the substrate S at the time of forming the liquid film can be quickly discharged and the adhesion of the liquid to the lower surface Sb itself can also be reduced.

In short, it is effective in suppressing the adhesion of the liquid to the lower surface Sb to provide a step of blowing the gas toward the lower surface Sb of the substrate S for a certain period after the supply of the processing liquid for liquid film formation is stopped, more preferably after the rotation of the substrate S is stopped and before the substrate S is conveyed to the supercritical processing apparatus 4 and placed on the support tray 415. Specifically, the gas may be blown until Step 5105 is finished after the start of Step S103 of FIG. 2.

### Second Embodiment

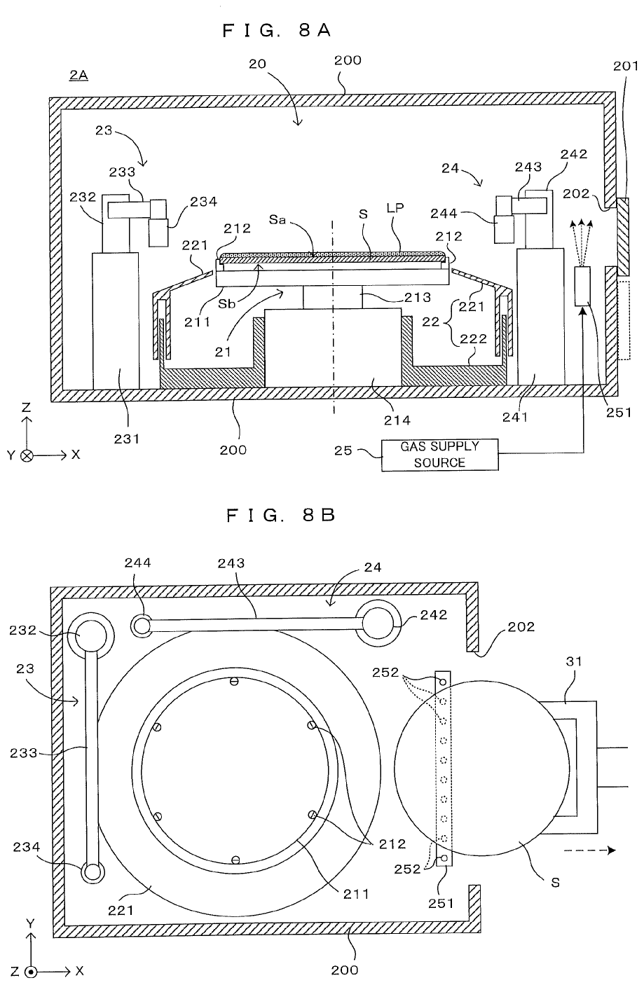

FIGS. 8A and 8B are diagrams showing a second embodiment for the blowing of a gas. More specifically, FIG. 8A is a side sectional view showing the internal structure of a wet processing apparatus 2B of the second embodiment, and FIG. 8B is a plan sectional view. In this embodiment, a gas nozzle 251 is arranged near an opening 202 provided with a shutter 201 in a processing chamber 200. As shown in FIG. 8B, the gas nozzle 251 is a multi-hole nozzle having an outer shape elongated along the Y direction and including a plurality of discharge ports 252 arrayed in the Y direction.

The gas nozzle 251 is arranged below a path for a substrate S when the substrate S placed on a spin chuck 211 is carried out via the opening 202, and the respective discharge ports 252 are open upward. As indicated by a dotted line arrow, when the substrate S is carried out by the hand 31 of the conveyor robot 30, a gas supplied from a gas supply source 25 is discharged upward from the respective discharge ports 252. Therefore, when the substrate S after the formation of the liquid film passes above the gas nozzle 251, the gas is blown to the lower surface of the substrate S, whereby the liquid adhering to the lower surface of the substrate S is blown off.

According to this configuration, even if the liquid flows around to the lower surface side from the upper surface side after the start of a movement of the substrate S to be carried out from the wet processing apparatus 2 after the formation of the liquid film, this liquid can be removed in the wet processing apparatus 2. Note that, to enhance a liquid removal effect, the hand 31 may be temporarily stopped or a moving speed thereof may be reduced, for example, when the substrate S being conveyed is at a position right above the nozzle 251.

### Third Embodiment

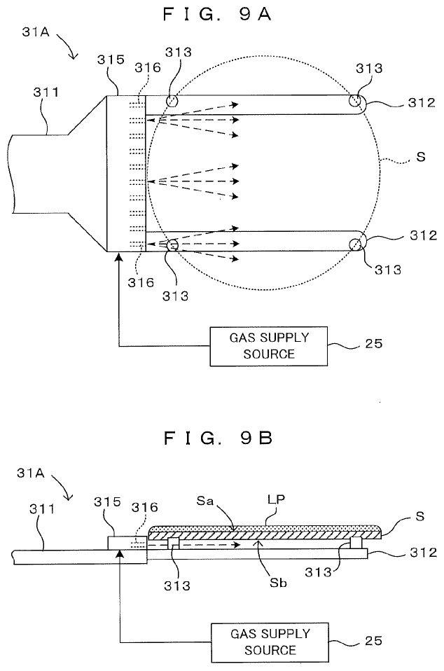

FIGS. 9A and 9B are diagrams showing a third embodiment for the blowing of a gas. In the first and second embodiments, a configuration for blowing the gas is provided in the wet processing apparatus 2. On the other hand, in this third embodiment, a conveyor robot 30 has a configuration for blowing a gas.

Specifically, a hand 31A of the conveyor robot 30 in this embodiment is structured such that two substrate supports 312 extend substantially in parallel from a base 311 attached to an unillustrated telescopic arm. Each substrate support 312 is provided with support pins 313 for supporting a substrate S by being partially held in contact with the underside and peripheral edge part of the substrate S. A gas nozzle 315 for blowing the gas is mounted on the base 311.

A plurality of discharge ports 316 are arrayed in a horizontal direction in the gas nozzle 315, and the gas nozzle 315 is a multi-hole nozzle. The respective discharge ports 316 are provided in a side surface of the gas nozzle 315 facing toward the substrate S and substantially horizontally discharge the gas supplied from the gas supply source 25. As shown in FIG. 9B, in a horizontal view, the discharge ports 316 are open below a lower surface Sb of the substrate S supported by the support pins 313 and blow the gas at a relatively narrow angle as shown by a broken line arrow. On the other hand, as shown by broken line arrows in FIG. 9A, the gas is blown at a relatively wide angle in the horizontal direction. Therefore, the gas spreads along the lower surface Sb of the substrate S and blows off the liquid adhering to this surface.

The hand 31A is stored in a cover 32 and advances to outside from the cover 32 if necessary. In the process of the conveyor robot 30 to receive the substrate S from the wet processing apparatus 2 and carry the substrate S into the supercritical processing apparatus 4, the hand 31A can take a state where the hand 31A is stored in the cover 32 and a state where the hand 31A advances from the cover 32 to a processing chamber 200 or 400. Therefore, the liquid blown off by blowing the gas only drops down into the cover 32 or the processing chamber 200, 400 and is prevented from scattering around.

The gas nozzle 315 discharges the gas from the discharge ports 316 for at least a part of a period during which the hand 31A holds the substrate S. The gas may be discharged over the entire period or may be constantly discharged regardless of the presence or absence of the substrate S. A flow rate of the gas may be constant or a period may be provided during which the flow rate is temporarily increased to enhance the liquid removal effect. In this embodiment, the gas can be blown from immediately after the start of the conveyance until immediately before the carry-in into the processing chamber 412.

Note that, if a nitrogen gas or the like is supplied into the cover 32 for the purpose of controlling an atmosphere in the cover 32 or protecting electrical and mechanical contact points of the conveyor robot 30, the gas can be supplied from the gas supply source 25 to the gas nozzle 315.

### Miscellaneous

As described above, in each of the above embodiments, the spin chuck 211 functions as a “substrate holder” of the invention. Further, the gas nozzle 216, 251, 315 functions as a “gas discharger” of the invention.

Note that the invention is not limited to the embodiments described above and various changes other than the aforementioned ones can be made without departing from the gist of the invention. For example, although the three embodiments have been described as configurations for blowing the gas to the substrate lower surface above, these can be carried out not only singly, but also with two or more combined.

Further, for example, in the above embodiments, the carbon dioxide is used as the processing fluid for supercritical processing, the nitrogen gas or dry air is used as the gas to be blown to the lower surface of the substrate and the IPA is used as the liquid for forming the liquid film. However, this is merely illustrative and chemical substances used are not limited to these.

As the specific embodiments have been illustrated and described above, a supercritical processing apparatus may be configured such that a substrate being conveyed by a conveyor device is supported in a horizontal posture by being placed on a flat plate-like support tray and a gas discharger blows a gas before the substrate is placed on a support tray in the substrate processing method according to the invention.

Further, for example, a wet processing apparatus may be configured such that a liquid film is formed with the substrate placed on a flat plate-like and rotating substrate holder and a gas discharger discharges a gas from a nozzle provided on the upper surface of the substrate holder. In this case, the gas discharger may blow the gas in a state where the rotation of the substrate holder is stopped after the formation of the liquid film.

Further, for example, the gas discharger may be configured to discharge the gas from a nozzle provided below a path for the substrate carried out from the wet processing apparatus in the wet processing apparatus. Further, a hand for holding the substrate may be provided in the conveyor device and the gas discharger may be configured to discharge the gas from a nozzle provided on the hand toward the substrate.

Here, a nitrogen gas or dry air can be suitably utilized as the gas to be discharged from the gas discharger.

Further, this invention can be realized as a substrate processing system provided with a wet processing apparatus for forming a liquid film on the upper surface of a substrate, a supercritical processing apparatus for accommodating the substrate having the liquid film formed thereon into a chamber and processing the substrate by a supercritical processing fluid and a conveyor device for carrying the substrate having the liquid film formed thereon into the chamber of the supercritical processing apparatus. For example, a nozzle can be arranged below a path for the substrate being carried out from the wet processing apparatus in the wet processing apparatus, and the nozzle can be configured to blow a gas to the lower surface of the substrate being carried out by the conveyor device. Alternatively, the conveyor device may be configured to include a hand for holding the substrate and a nozzle provided in the hand to blow a gas to the lower surface of the substrate held by the hand.

These substrate processing systems can be configured such that the nozzle blows the gas toward the lower surface of the substrate supported in a horizontal posture, for example, for at least a part of a period after the formation of the liquid film on the substrate during which the substrate is outside the chamber.

Further, for example, if the supercritical processing apparatus includes a flat plate-like support tray to be accommodated into the chamber with the substrate placed thereon, the nozzle preferably blows the gas before the substrate is placed on the support tray. By doing so, the entrance of the liquid into a gap between the substrate and the support tray is suppressed and problems such as a long time required for the replacement of the liquid and processing failures caused by the remaining liquid can be avoided in the supercritical processing.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

The invention can be applied to substrate processing apparatuses in general for processing a substrate using a supercritical fluid. Particularly, the invention can be suitably applied for a substrate drying processing for drying a substrate such as a semiconductor substrate by a supercritical fluid.

What is claimed is:

1. A substrate processing method, comprising:
forming a liquid film on an upper surface of a substrate by a wet processing apparatus;
carrying the substrate having the liquid film formed thereon into a chamber of a supercritical processing apparatus by a conveyor device;
processing a substrate by a processing fluid in a supercritical state in the chamber by the supercritical processing apparatus; and
blowing a gas toward a lower surface of the substrate supported in a horizontal posture by a gas discharger for at least a part of a period after the formation of the liquid film on the substrate during which the substrate is outside the chamber.

2. The substrate processing method according to claim 1, wherein:
the substrate is supported in the horizontal posture by placing the substrate being conveyed by the conveyor device on a flat plate-like support tray in the supercritical processing apparatus, and
the gas discharger blows the gas before the substrate is placed on the support tray.

3. The substrate processing method according to claim 1, wherein:
the wet processing apparatus forms the liquid film with the substrate placed on an upper surface of a flat plate-like and rotating substrate holder, and
the gas discharger discharges the gas from a nozzle provided on the upper surface of the substrate holder.

4. The substrate processing method according to claim 3, wherein the gas discharger blows the gas in a state where rotation of the substrate holder is stopped after the formation of the liquid film.

5. The substrate processing method according to claim 1, wherein the gas discharger discharges the gas from a nozzle provided below a path for the substrate being carried out from the wet processing apparatus in the wet processing apparatus.

6. The substrate processing method according to claim 1, wherein:
the conveyor device is provided with a hand for holding the substrate, and
the gas discharger discharges the gas toward the substrate from a nozzle provided on the hand.

7. The substrate processing method according to claim 1, wherein the gas is a nitrogen gas or dry air.

8. A substrate processing system, comprising:
a wet processing apparatus configured to form a liquid film on an upper surface of a substrate;
a supercritical processing apparatus having a chamber configured to accommodate the substrate having the liquid film formed thereon and processing the substrate by a supercritical processing fluid in the chamber; and
a conveyor device configured to carry the substrate having the liquid film formed thereon into the chamber of the supercritical processing apparatus, wherein
the wet processing apparatus has a nozzle being arranged below a path for the substrate being carried out, the nozzle blowing a gas toward a lower surface of the substrate being carried out by the conveyor device.

9. The substrate processing system according to claim 8, wherein:
the nozzle blows the gas toward the lower surface of the substrate supported in a horizontal posture for at least a part of a period after the formation of the liquid film on the substrate during which the substrate is outside the chamber.

10. The substrate processing system according to claim 9, wherein:
the supercritical processing apparatus includes a flat plate-like support tray to be accommodated into the chamber with the substrate placed thereon, and
the nozzle blows the gas before the substrate is placed on the support tray.

11. A substrate processing system, comprising:
a wet processing apparatus configured to form a liquid film on an upper surface of a substrate;
a supercritical processing apparatus having a chamber configured to accommodate the substrate having the liquid film formed thereon and processing the substrate by a supercritical processing fluid in the chamber; and
a conveyor device configured to carry the substrate having the liquid film formed thereon into the chamber of the supercritical processing apparatus, wherein
the conveyor device includes a hand configured to hold the substrate and a nozzle provided on the hand so as to blow a gas to a lower surface of the substrate held by the hand.

12. The substrate processing system according to claim 11, wherein:
the nozzle blows the gas toward the lower surface of the substrate supported in a horizontal posture for at least a part of a period after the formation of the liquid film on the substrate during which the substrate is outside the chamber.

13. The substrate processing system according to claim 12, wherein:
the supercritical processing apparatus includes a flat plate-like support tray to be accommodated into the chamber with the substrate placed thereon, and
the nozzle blows the gas before the substrate is placed on the support tray.
